(19) United States
(12) Patent Application Publication
(10) Pub. No.: US 2022/0320424 A1
(43) Pub. Date: Oct. 6, 2022

(54) SELECTOR AND PREPARATION METHOD THEREOF

(71) Applicant: INSTITUTE OF MICROELECTRONICS OF THE CHINESE ACADEMY OF SCIENCES, BEIJING (CN)

(72) Inventors: Qing LUO, Beijing (CN); Yaxin DING, Beijing (CN); Hangbing LV, Beijing (CN); Ming LIU, Beijing (CN)

(73) Assignee: INSTITUTE OF MICROELECTRONICS OF THE CHINESE ACADEMY OF SCIENCES, BEIJING (CN)

(21) Appl. No.: 17/310,922

(22) PCT Filed: Dec. 14, 2020
(86) PCT No.: PCT/CN2020/136212

§ 371 Date: Aug. 31, 2021

(30) Foreign Application Priority Data
Jul. 22, 2020 (CN) 202010714397.6

(51) Int. Cl. H01L 45/00

(52) U.S. Cl. CPC H01L 45/1233; H01L 45/1608; H01L 45/1691

(57) ABSTRACT

The disclosure discloses a selector and a preparation method thereof. The selector includes: a substrate 1; an alternating layer 2 provided on the substrate 1, the alternating layer 2 being alternately formed by a bottom electrode layer 21 and an insulating layer 22; the alternating layer 2 is provided with a U-shaped groove; a selective layer 3 and a dielectric layer 4 being sequentially deposited in a direction from an inner wall of the U-shaped groove to a center of the U-shaped groove; and a top electrode layer 5 is filled in a concave space defined by the dielectric layer 4. The selector and the preparation method according to one or more embodiments of the disclosure can address the technical problem of high leakage current of the selector in existing technology and provide a selector with low leakage current.

### CROSS-REFERENCES TO RELATED APPLICATIONS

This disclosure claims the priority of the Chinese patent application No. 202010714397.6 filed on Jul. 22, 2020, entitled “a selector and preparation method thereof”, the entire content of which is incorporated herein by reference.

### TECHNICAL FIELD

The disclosure relates to the field of semiconductors, and more particularly to a selector and a preparation method thereof.

### BACKGROUND OF THE INVENTION

With the development of memory technology, higher requirements are put forward for the density and scalability of memory. Memory with crossbar structure has high storage density and excellent scalability ,becoming a strong competitor in the memory field. However, the high leakage current problem of the cross-point memory needs to be solved urgently, and the selector is considered to be a powerful candidate to solve the leakage current problem.

The selector has the advantages such as high on-state current density and fast switching speed, but the high leakage current is a major problem to its application in the memory array.

### SUMMARY OF THE INVENTION

The aim of the disclosure is, at least in part, to provide a selector with improved performance and a preparation method thereof.

In one aspect of the disclosure, a selector is provided, including:

a substrate;

an alternating layer deposited on the substrate, the alternating layer is alternately formed by a bottom electrode layer and an insulating layer; the alternating layer is provided with a U-shaped groove, a selective layer and a dielectric layer being sequentially deposited in a direction from an inner wall of the U-shaped groove to a center of the U-shaped groove, and a top electrode layer is filled in a concave space defined by the dielectric layer.

In some embodiments, the bottom electrode layer may be a TiN layer; the insulating layer may be a SiO₂ layer.

In some embodiments, the selective layer may be an oxide layer of niobium, and a thickness of the selective layer may be 25-40 nm.

In some embodiments, the dielectric layer may be an HfO₂ layer, and the thickness of the dielectric layer may be 18-22 nm.

In some embodiments, the top electrode layer may be a Pt layer, and the width of the top electrode layer located in the concave space may be 45-55 nm.

In another aspect of the disclosure, a method for preparing a selector is provided , including:
forming an alternating layer on a substrate, the alternating layer is alternately formed by a bottom electrode layer and an insulating layer;
etching the alternating layer to form a U-shaped groove;
sequentially forming a selective layer and a dielectric layer on an inner wall of the U-shaped groove;
filling a top electrode layer in a concave space defined by the dielectric layer.

In some embodiments, the forming an alternating layer on a substrate includes: forming an alternating layer alternately formed by a TiN layer and a SiO₂ layer on a substrate.

In some embodiments, the sequentially forming a selective layer and a dielectric layer on an inner wall of the U-shaped groove includes: striking a target material including a Nb element and an O element by adopting a magnetron sputtering process, and forming a selective layer by depositing an oxide of niobium on an inner wall of the U-shaped groove under an condition that an oxygen flux is 0.6-1.0 sccm; and forming the dielectric layer on the selective layer.

In some embodiments, the sequentially forming a selective layer and a dielectric layer on an inner wall of the U-shaped groove includes: forming a selective layer on an inner wall of the U-shaped groove; forming a dielectric layer by depositing HfO₂ on the selective layer through adopting an atomic layer deposition process.

In some embodiments, the filling a top electrode layer in a concave space defined by the dielectric layer includes: forming a top electrode layer by depositing Pt in a concave space defined by the dielectric layer through adopting a magnetron sputtering process, and a width of the top electrode layer located in the concave space is 45-55 nm.

According to one or more technical solutions provided in the disclosure, a three- dimensional device structure is formed by forming a U-shaped groove on the alternating layer formed by the bottom electrode layer and the insulating layer alternating with each other, then providing the selective layer and the dielectric layer in the U-shaped groove, and filling a top electrode layer in the concave space defined by the dielectric layer. Since the selective layer located in the U-shaped groove in the three-dimensional device structure contacts a cross section of the bottom electrode layer on the sidewall of the U-shaped groove, the contact area between the selective layer and the bottom electrode layer is greatly reduced, thereby limiting the thermal effect and reducing the leakage current of the selector. By inserting a suitable dielectric layer between the selective layer and the top electrode layer, a narrower conductive filament is formed; a portion of the dielectric layer where no conductive filament exists has a higher resistance, thereby suppressing the defects in the selective layer, which further limits the thermal effect, and eventually effectively reduces the leakage current of the selector.

### BRIEF DESCRIPTION OF THE DRAWINGS

In order to more clearly describe the technical solutions in the embodiments of the disclosure, the following will briefly introduce the drawings needed in the description of the embodiments. Obviously, the drawings in the following description are merely embodiments of the disclosure. For those of ordinary skill in the art, without creative work, other drawings can be obtained based on the provided drawings.

FIG. 1 is a structural diagram of a selector according to one or more embodiments of the disclosure.

FIG. 2 is a partial diagram of the dashed box in FIG. 1.

FIG. 3 is a flowchart of a method for preparing a selector according to one or more embodiments of the disclosure.

FIG. 4 is a first process diagram of a selector according to one or more embodiments of the disclosure.

FIG. 5 is a second process diagram of a selector according to one or more embodiments of the disclosure.

FIG. 6 is the third process diagram of the selector according to one or more embodiments of the disclosure.

### DETAILED DESCRIPTION OF THE INVENTION

Embodiments of the disclosure will be described with reference to the drawings hereinafter. However, it should be understood that these descriptions are only exemplary and are not intended to limit the scope of the disclosure. In addition, in the following description, descriptions of well- known structures and technologies are omitted to avoid unnecessarily obscuring the concept of the disclosure.

The drawings show various structural schematic diagrams according to the embodiments of the disclosure. These figures are not drawn to scale, some details are enlarged and some details may be omitted for clarity of presentation. The shapes of the various areas and layers shown in the figure, as well as the relative size and positional relationship between them, are only exemplary; in practice, there may be deviations due to fabricating tolerances or technical limitations. Areas/layers with different shapes, sizes, and relative positions can be designed by those skilled in the art as needed.

In the context of the disclosure, when a layer/element is referred to as being “on” another layer/element, the layer/element may be directly on the other layer/element, or there may be an intermediate layer/element between them. In addition, if a layer/element is located “on” another layer/element in an orientation, the layer/element may be located “under” the other layer/element when the orientation is reversed. In the context of the disclosure, similar or identical components may be denoted by the same or similar reference numerals.

In order to better understand the above technical solutions, the above technical solutions will be described in detail hereinafter in conjunction with specific implementations. It should be understood that the embodiments of the disclosure and the specific features in the embodiments are detailed descriptions of the technical solutions of the disclosure and are not for limiting the technical solution of the disclosure. The embodiments of the disclosure and the technical features in the embodiments can be combined with each other if there is no conflict.

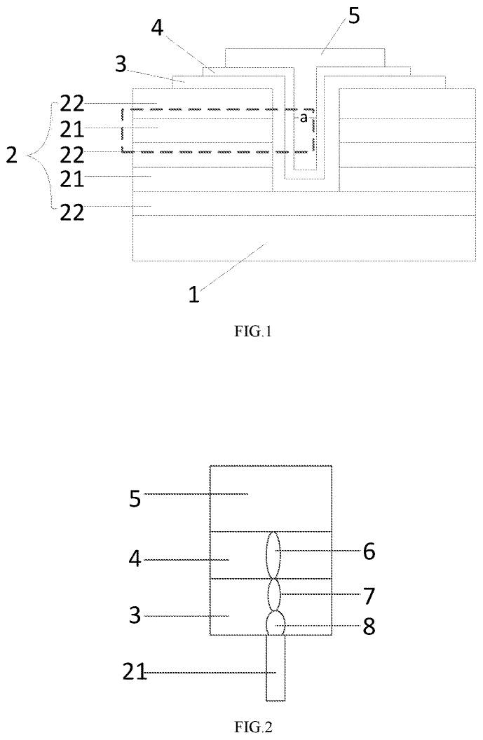

According to one aspect of the disclosure, a selector is provided, as shown in FIG. 1 and FIG. 2, including:

a substrate 1;

an alternating layer 2 deposited on the substrate 1, the alternating layer 2 is alternately formed by a bottom electrode layer 21 and an insulating layer 22; a U-shaped groove formed on the alternating layer 2, and a selective layer 3 and a dielectric layer 4 are sequentially deposited in a direction from an inner wall of the U-shaped groove to a center of the U-shaped groove, and a top electrode layer 5 is filled in a concave space defined by the dielectric layer 4.

It should be noted that FIG. 1 is a structural diagram of a selector according to one or more embodiments of the disclosure, and FIG. 2 is a partial diagram of the dashed box in FIG. 1. Specifically, FIG. 2 is a partial diagram formed by cutting off the region in the dashed box and turning the region through 90° counterclockwise after removing the insulating layer 22.

Specifically, the substrate 1 may be a Si substrate, a SiO₂ substrate, or a substrate composed of Si and SiO₂. In some embodiments, the substrate 1 can be made to have Si on the lower side and SiO₂ on the upper side, so as to have better transition with the insulating layer 22 in the alternating layer 2 on the substrate 1 through SiO₂.

In some embodiments, the number of layers of the bottom electrode layer 21 and the insulating layer 22 in the alternating layer 2 is not limited. Specifically, the bottom electrode layer 21 can be 1-8 layers, and the insulating layer 22 can be 2-9 layers, and for sure, it can also be more than 8 layers. For example, the alternating layer 2 can be insulating layer 22- bottom electrode layer 21—insulating layer 22—bottom electrode layer 21—insulating layer 22—bottom electrode layer 21—insulating layer 22—bottom electrode layer 21—insulating layer 22—bottom electrode layer 21—insulating layer 22 sequentially deposited upwards from the substrate 1; that is, five bottom electrode layers 21 and six insulating layers 22 alternate to form the alternating layer 2. In some embodiments, the lowermost and uppermost layers of the alternating layer 2 are both insulating layers 2.

In some embodiments, the bottom electrode layer 21 may be a TiN layer, and the insulating layer 22 may be a SiO₂ layer. A thickness of the bottom electrode layer 21 is 20-30 nm per layer, and a thickness of the insulating layer 22 is greater than that of the bottom electrode layer 21 so as to reduce the contact area between the bottom electrode layer 21 and the selective layer 3. Of course, the bottom electrode layer 21 can also be a metal layer such as W, Pt, Au, or a nitride layer of W, Pt, Au, etc., which is not limited herein. The insulating layer 22 may also be an insulating layer such as C, SiC, etc., which is not limited herein.

In some embodiments, the alternating layer 2 is provided with a U-shaped groove. The U- shaped groove is formed from the uppermost layer to the lowermost layer of the alternating layer 2, and the uppermost layer and the lowermost layer may be insulating layer 22. The bottom electrode layer 21 is not retained on the bottom surface of the U-shaped groove, so that a contact portion between the bottom electrode layer 21 and the selective layer 3 is only a side cutting face of the bottom electrode layer 21, reducing contact area.

In some embodiments, the selective layer 3 is an oxide layer of niobium, such as NbOx, and X is a positive number. The thickness of the selective layer 3 is 25-40 nm. Since the selector of the NbOx type selective layer material has a high on-state current and a fast switching speed, but has a problem of high leakage current, the structure of the embodiments can effectively retain beneficial effects and effectively solve the problem of high leakage current. Of course, the selective layer 3 may also be a material with threshold transition properties such as a chalcogenide compound, which is not limited herein.

In some embodiments, as shown in FIG. 1, the bottom of the selective layer 3 in the U- shaped groove is in contact with the insulating layer 22, and a portion of the selective layer 3 positioned on an inner sidewall of the groove contacts the side cutting face of the bottom electrode layer 21. The selective layer 3 may extend to the upper surface of the alternating layer 2 as shown in FIG. 1.

In some embodiments, the dielectric layer 4 is an HfO₂ layer, and the thickness of the dielectric layer 4 is 18-22 nm. Due to the electrothermal properties (high resistance) of HfO₂ material, the current can be effectively reduced during the use of the selector, the conduction area is reduced, and the thermal effect is limited, thereby further reducing the leakage current of the selector. Of course, the dielectric layer 4 can also be other materials with higher resistance and capable of generating conductive filaments (for example, NiOx, Al₂O₃, etc.), which is not limited herein.

In some embodiments, the top electrode layer 5 is a Pt layer. As shown in FIG. 1, the width a of the top electrode layer 5 in the concave space defined by the dielectric layer 4 is 45-55 nm. Of course, the top electrode layer 5 can also be a metal layer such as W, Au, etc., which is not limited herein.

The top electrode layer 5 is deposited in the concave space, as shown in FIG. 2. The width a of the top electrode layer 5 is made wide enough to ensure the roughness of the contact surface with the dielectric layer 4, so as to reduce the area of the conductive filament 6 produced by the dielectric layer 4, thereby suppressing defects in the selective layer 3 and limiting the thermal effect. The Joule generated at the contact surface between the selective layer 3 and the bottom electrode layer 21 is limited by reducing the contact area between the selective layer 3 and the bottom electrode layer 21, which is the first Joule heating limit 8. Therefore, through these two limitations, a second Joule heating limit 7 is finally generated for the selective layer 3, which further reduces the leakage current.

In another aspect of the disclosure, a method for preparing the aforementioned selector is also provided, which is described in detail as follows.

The disclosure provides a method for preparing a selector, as shown in FIG. 3, including:

Step S301, forming an alternating layer on a substrate, the alternating layer being alternately formed by a bottom electrode layer and an insulating layer;

Step S302, etching the alternating layer to form a U-shaped groove;

Step S303, sequentially forming a selective layer and a dielectric layer on an inner wall of the U-shaped groove; and

Step S304, filling a top electrode layer in a concave space defined by the dielectric layer.

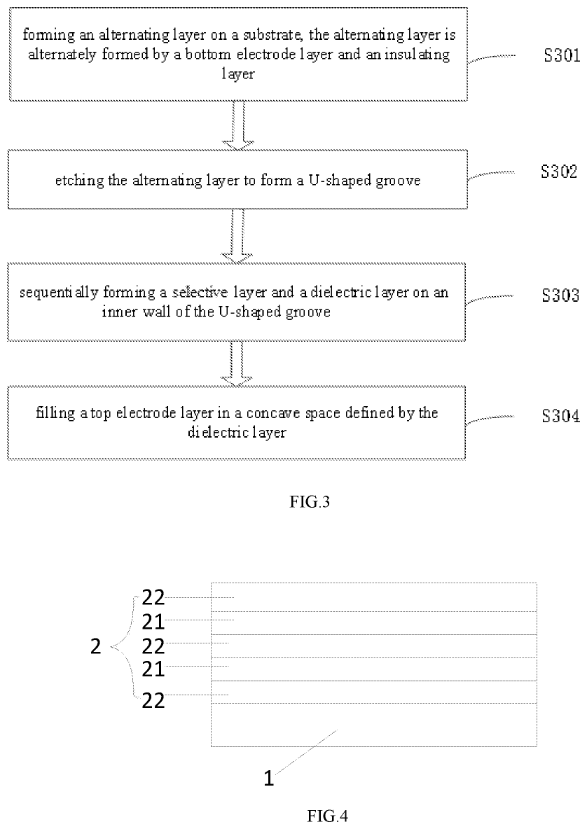

The method for preparing the selector will be described in detail below with reference to FIG. 4-FIG. 6.

First, as shown in FIG. 4, an alternating layer 2 is formed on a substrate 1. Preferably, the alternating layer 2 may be formed by a TiN layer (bottom electrode layer) and a SiO₂ layer (insulating layer) alternately formed on the substrate 1. Specifically, the alternating layer 2 may be formed by deposition techniques such as Physical Vapor Deposition (PVD) or Plasma Enhanced Chemical Vapor Deposition (PECVD), which is not limited herein.

Of course, the bottom electrode layer 21 can also be a metal layer such as W, Pt, Au, or a nitride layer of W, Pt, Au, etc., which is not limited herein. The insulating layer 22 may also be an insulating layer such as C, SiC, etc., which is not limited herein.

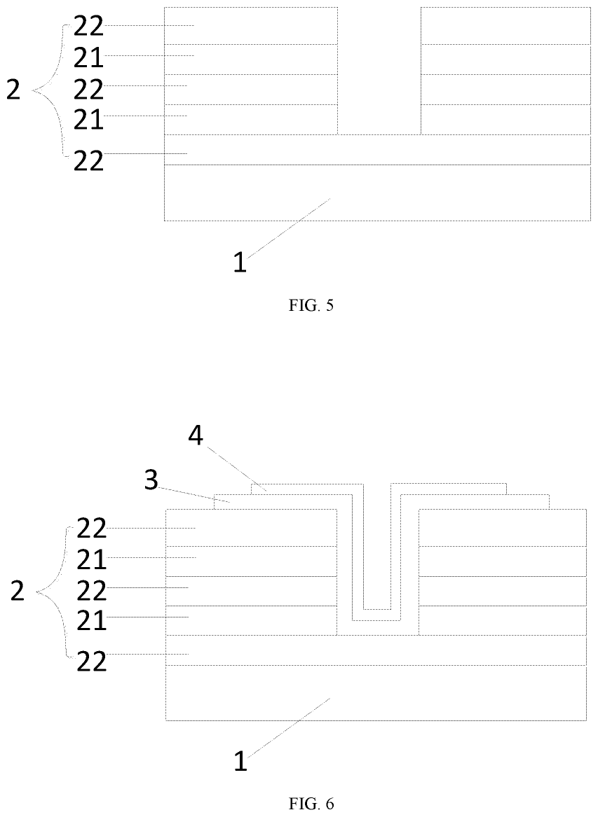

Then, as shown in FIG. 5, the alternating layer 2 is etched to form a U-shaped groove. Specifically, the etching is made until the bottom surface of the U-shaped groove is the insulating layer 22. The etching process can be wet etching or dry etching, etc., which is not limited herein.

Next, as shown in FIG. 6, a selective layer 3 and a dielectric layer 4 are sequentially formed on the inner wall of the U-shaped groove.

In some embodiments, the selective layer 3 is an oxide layer of niobium. The specific process can be adopting magnetron sputtering to strike a target material including a Nb element and an O element under an Ar and O₂ environment. Under a condition that an oxygen flux is 0.6-1.0 sccm (0.8 sccm of oxygen flux is optimal), an oxide of niobium is deposited on the inner wall of the U-shaped groove to form the selective layer. The mass ratio of Nb:O of the target material can be 1:1 or other ratios, which is not limited herein. Specifically, the selective layer 3 formed by adopting magnetron sputtering technology has fewer defects and is more even. Of course, the selective layer 3 may also be a material having threshold transition properties such as a chalcogenide compound. It is also possible to use processes such as evaporation or chemical deposition to form the selective layer 3, which is not limited herein.

In some embodiments, atomic layer deposition (ALD) may be used to deposit HfO₂ on the selective layer 3 to form the dielectric layer 4, so as to ensure the compactness of the dielectric layer 4 and reduce an area of generating conductive filaments. Of course, the dielectric layer 4 can also be a semiconductor material such as doped silicon. The dielectric layer 4 can also be formed by adopting evaporation process or chemical deposition process, etc., which is not limited herein.

Next, as shown in FIG. 1, the top electrode layer 5 is filled in the concave space defined by the dielectric layer 4.

In some embodiments, for the top electrode layer 5, a magnetron sputtering process can be used to deposit Pt in the concave space defined by the dielectric layer to form the top electrode layer 5, and the width of the top electrode layer 5 located in the concave space is 45˜55 nm. Of course, the top electrode layer 5 can also be a metal layer such as W, Au, etc., which is not limited herein.

It should be noted that the selective layer 3, the dielectric layer 4 and the top electrode layer 5 may extend to the surface of the alternating layer 2 as shown in FIG. 1, or may only be located in the U-shaped groove area, which is not limited herein.

The above-mentioned technical solutions in the embodiments of the disclosure have at least the following technical effects or advantages:

according to the selector and the preparation method thereof provided by the embodiments of the disclosure, a three-dimensional device structure is formed by forming a U-shaped groove on the alternating layer formed by the bottom electrode layer and the insulating layer alternating with each other, then providing the selective layer and the dielectric layer in the U-shaped groove, and filling a top electrode layer in the concave space defined by the dielectric layer. Since the selective layer located in the U-shaped groove in the three-dimensional device structure contacts a cross section of the bottom electrode layer on the sidewall of the U-shaped groove, the contact area between the selective layer and the bottom electrode layer is greatly reduced, thereby limiting the thermal effect and reducing the leakage current of the selector. By inserting a suitable dielectric layer between the selective layer and the top electrode layer, a narrower conductive filament is formed; a portion of the dielectric layer where no conductive filament exists has a higher resistance, thereby suppressing the defects in the selective layer, which further limits the thermal effect, and eventually effectively reduces the leakage current of the selector.

In the above-mentioned description, the technical details such as patterning of each layer and etching have not been described in detail. However, those skilled in the art should understand that various technical means can be used to form layers, regions, etc., of a desired shape. In addition, in order to form the same structure, those skilled in the art can also design a method that is not completely the same as the method described above. In addition, although each embodiment is described separately above, this does not mean that the measures in the various embodiments cannot be advantageously used in combination.

Obviously, those skilled in the art can make various changes and modifications to the disclosure without departing from the spirit and scope of the disclosure. In this way, if these modifications and variations of the disclosure fall within the scope of the claims of the disclosure and equivalent technologies thereof, the disclosure is also intended to include these modifications and variations.

1. A selector, comprising:
a substrate;
an alternating layer deposited on the substrate, the alternating layer being alternately formed by a bottom electrode layer and an insulating layer;
the alternating layer is provided with a U-shaped groove, a selective layer and a dielectric layer being sequentially deposited in a direction from an inner wall of the U-shaped groove to a center of the U-shaped groove, and a top electrode layer is filled in a concave space defined by the dielectric layer.

2. The selector of claim 1, wherein the bottom electrode layer is a TiN layer; the insulating layer is a SiO₂ layer.

3. The selector of claim 1, wherein the selective layer is an oxide layer of niobium, and a thickness of the selective layer is 25-40 nm.

4. The selector of claim 1, wherein the dielectric layer is an HfO₂ layer, and a thickness of the dielectric layer is 18-22 nm.

5. The selector of claim 1, wherein the top electrode layer is a Pt layer, and a width of the top electrode layer located in the concave space is 45-55 nm.

6. A method for preparing a selector, comprising:
forming an alternating layer on a substrate, the alternating layer is alternately formed by a bottom electrode layer and an insulating layer;
etching the alternating layer to form a U-shaped groove;
sequentially forming a selective layer and a dielectric layer on an inner wall of the U-shaped groove; and
filling a top electrode layer in a concave space defined by the dielectric layer.

7. The method of claim 6, wherein the forming an alternating layer on a substrate includes:
forming the alternating layer alternately formed by a TiN layer and a SiO₂ layer on the substrate.

8. The method of claim 6, wherein said sequentially forming a selective layer and a dielectric layer on an inner wall of the U-shaped groove includes:
striking a target material including a Nb element and an O element by adopting a magnetron sputtering process, and forming a selective layer by depositing an oxide of niobium on an inner wall of the U-shaped groove under an condition that an oxygen flux is 0.6-1.0 sccm; and
forming the dielectric layer on the selective layer.

9. The method of claim 6, wherein said sequentially forming a selective layer and a dielectric layer on an inner wall of the U-shaped groove includes:
forming the selective layer on the inner wall of the U-shaped groove; and
forming the dielectric layer by depositing HfO₂ on the selective layer through adopting an atomic layer deposition process.

10. The method of claim 6, wherein said filling a top electrode layer in a concave space defined by the dielectric layer includes:
forming a top electrode layer by depositing Pt in the concave space defined by the dielectric layer through adopting a magnetron sputtering process, and a width of the top electrode layer located in the concave space is 45-55 nm.
